(19) United States
(12) Patent Application Publication
(10) Pub. No.: US 2025/0357389 A1
(43) Pub. Date: Nov. 20, 2025

(54) APPARATUS AND METHODS FOR TRANSMISSION LINE TERMINATION IN DIE STACKING CONFIGURATIONS

(71) Applicant: Sandisk Technologies, Inc., Milpitas, CA (US)

(72) Inventors: Mohammad Mahmoodi, Santa Barbara, CA (US); Zahra Fahimi, Santa Barbara, CA (US); Martin Lueker-Boden, Fremont, CA (US)

(73) Assignee: Sandisk Technologies, Inc., Milpitas, CA (US)

(21) Appl. No.: 18/668,745

(22) Filed: May 20, 2024

(51) Int. Cl. H01L 23/64; H01L 23/00; H01L 23/522; H01L 23/60; H01L 25/065; H10B 80/00

(52) U.S. Cl. CPC H01L 23/647; H01L 23/5226; H01L 23/60; H01L 24/48; H01L 25/0657; H10B 80/00; H01L 2224/48145; H01L 2224/48227; H01L 2225/06506; H01L 2225/0651; H01L 2225/06562

(57) ABSTRACT

An apparatus is provided that includes a die stack that includes multiple die disposed above a substrate. Each die includes a bond pad, a resistor and a transmitter/receiver circuit, and wire bonds connect the bond pads of the multiple die. Each resistor is coupled between a corresponding one of the bond pads and a corresponding one of the transmitter/receiver circuits. The resistors are configured to increase an impedance of a transmission line that includes the wire bonds.

### BACKGROUND

The strong demand for portable consumer electronics devices is driving the need for high-capacity storage devices. Non-volatile semiconductor memory devices, such as flash memory storage cards, are increasingly used to meet ever-growing demands on digital information storage and exchange. Their portability, versatility and rugged design, along with their high reliability and large capacity, have made such memory devices ideal for use in a wide variety of electronic devices.

Semiconductor devices are sometimes formed in a System in a Package (SiP) device that includes multiple semiconductor die mounted in a stack on a substrate. The die are often electrically coupled to the one another and to the substrate using wire bonds. This same die-stacking technology is also used for non-volatile semiconductor memory devices. In some semiconductor memory devices the stack may include four or more memory die.

A challenge for die stacking technology is satisfying signal integrity requirements, which pertains to the quality of signals communicated between die within the same package and between die in separate packages. Maintaining signal integrity requires properly terminating a transmission line on which the signals are communicated. For stacked memory die, the transmission lines includes the wire bonds that are coupled to and route signals to and from the memory die. This intra-die routing typically has very low impedance.

Properly terminating such low impedance transmission lines requires using very low termination values, which increases power consumption and requires use of non-standard termination values. For semiconductor memory devices, both factors may negatively limit the use of such memory devices. Thus, alternative techniques are needed for maintaining signal integrity in stacked memory die.

### BRIEF DESCRIPTION OF THE DRAWINGS

Like-numbered elements refer to common components in the different figures.

FIG. 1 depicts an embodiment of a memory system.

FIG. 2 depicts an embodiment of a memory card containing multiple memory packages.

FIGS. 3A-3C depict side, top and perspective views, respectively, of a previously known semiconductor device that includes a semiconductor die stack.

FIG. 4 is a diagram of a simplified electrical model of a shared line of FIG. 1C.

FIGS. 5A-5C are more detailed equivalent electrical circuits looking into a transmitter/receiver circuit of FIG. 4.

FIGS. 6A-6C are equivalent electrical circuits looking into a modified transmitter/receiver circuit.

FIG. 7 is a diagram of a simplified electrical model of a shared line of FIG. 1C including a boosting resistor and a modified transmitter/receiver circuit.

FIGS. 8A-8E are simplified diagrams depicting various techniques that may be used to implement a boosting resistor.

FIG. 9 is a flow diagram of a method of terminating a transmission line in a die stack above a substrate.

### DETAILED DESCRIPTION

Technology is described for improving signal integrity in multi-die stacking configurations. In embodiments, on each die in a die stack a resistor is added between a bond pad and a transmitter/receiver circuit. In embodiments, the added resistor has relatively small value (e.g., 10Ω), and a resistance of a transmitter/receiver circuit is reduced by the resistance value of the added resistor.

Without wanting to be bound by any particular theory, it is believed that the added resistor boosts a characteristic impedance of the intra-die routing. Without wanting to be bound by any particular theory, it is believed that the disclosed technology may improve signal integrity and allow use of standard termination values in die stacking configurations. Without wanting to be bound by any particular theory, it is believed that the disclosed technology may improve signal integrity and reduce power consumption in die stacking configurations.

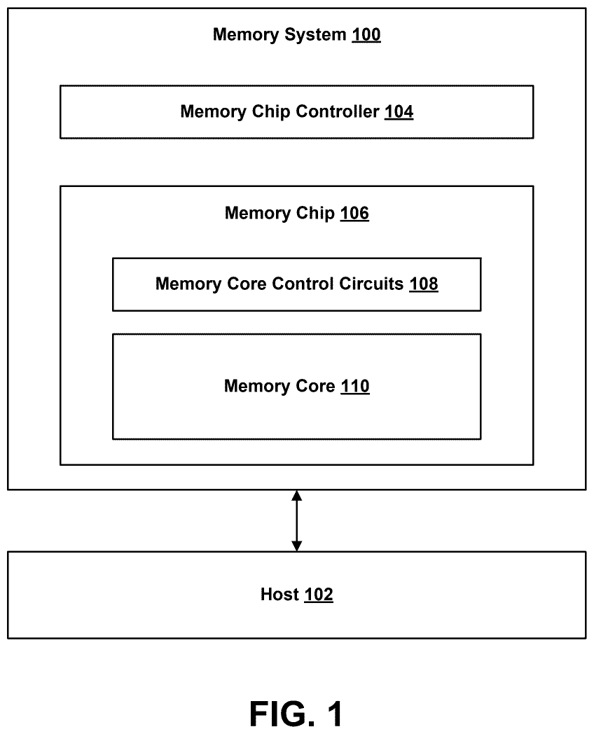

FIG. 1 depicts one embodiment of a memory system 100 and a host 102. Memory system 100 may include a non-volatile storage system interfacing with host 102 (e.g., a mobile computing device or a server). In some cases, memory system 100 may be embedded within host 102. As examples, memory system 100 may be a memory card, a solid-state drive (SSD) such a high density MLC SSD (e.g., 2-bits/cell or 3-bits/cell) or a high performance SLC SSD, or a hybrid HDD/SSD drive.

As depicted, memory system 100 includes a memory chip controller 104 and a memory chip 106. Memory chip 106 may include volatile memory and/or non-volatile memory. Although a single memory chip is depicted, memory system 100 may include more than one memory chip. Memory chip controller 104 may receive data and commands from host 102 and provide memory chip data to host 102.

Memory chip controller 104 may include one or more of control circuitry, state machines, page registers, SRAM, decoders, sense amplifiers, read/write circuits, and/or controllers, or any combination thereof, for controlling the operation of memory chip 106. The one or more control circuitry, state machines, page registers, SRAM, decoders, sense amplifiers, read/write circuits, and/or controllers for controlling the operation of the memory chip may be referred to as managing or control circuits. The managing or control circuits may facilitate one or more memory array operations including forming, erasing, programming, or reading operations.

In some embodiments, the managing or control circuits (or a portion of the managing or control circuits) for facilitating one or more memory array operations may be integrated within memory chip 106. Memory chip controller 104 and memory chip 106 may be arranged on a single integrated circuit or arranged on a single die. In other embodiments, memory chip controller 104 and memory chip 106 may be arranged on different integrated circuits. In some cases, memory chip controller 104 and memory chip 106 may be integrated on a system board, logic board, or a PCB.

Memory chip 106 includes memory core control circuits 108 and a memory core 110. Memory core control circuits 108 may include logic for controlling the selection of memory blocks (or arrays) within memory core 110, controlling the generation of voltage references for biasing a particular memory array into a read or write state, and generating row and column addresses.

Memory core 110 may include one or more two-dimensional arrays of memory cells and/or one or more three-dimensional arrays of memory cells. In an embodiment, memory core may include re-writable memory cells, one-time programmable memory cells, and/or multi-time programmable memory cells, or any combination thereof.

In an embodiment, memory core control circuits 108 and memory core 110 may be arranged on a single integrated circuit. In other embodiments, memory core control circuits 108 (or a portion of memory core control circuits 108) and memory core 110 may be arranged on different integrated circuits.

A memory operation may be initiated when host 102 sends instructions to memory chip controller 104 indicating that host 102 would like to read data from memory system 100 or write data to memory system 100. In the event of a write (or programming) operation, host 102 may send to memory chip controller 104 both a write command and the data to be written.

Memory chip controller 104 may buffer data to be written and may generate error correction code (ECC) data corresponding with the data to be written. The ECC data, which allows data errors that occur during transmission or storage to be detected and/or corrected, may be written to memory core 110 or stored in non-volatile memory within memory chip controller 104. In an embodiment, the ECC data are generated and data errors are corrected by circuitry within memory chip controller 104.

Memory chip controller 104 may control operation of memory chip 106. In an example, before issuing a write operation to memory chip 106, memory chip controller 104 may check a status register to make sure that memory chip 106 is able to accept the data to be written.

In another example, before issuing a read operation to memory chip 106, memory chip controller 104 may pre-read overhead information associated with the data to be read. The overhead information may include ECC data associated with the data to be read or a redirection pointer to a new memory location within memory chip 106 in which to read the data requested.

Once memory chip controller 104 initiates a read or write operation, memory core control circuits 108 may generate appropriate bias voltages and/or currents for word lines and bit lines within memory core 110, as well as generate the appropriate memory block, row, and column addresses.

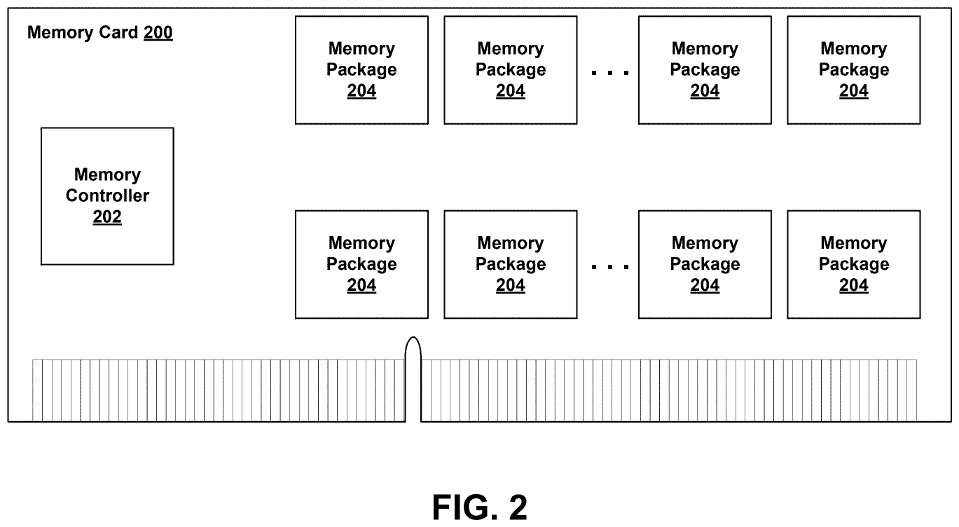

As described above, in an embodiment memory system 100 may be a memory card such as memory card 200 of FIG. 2. In an embodiment, memory card 200 includes a memory controller 202 and multiple memory packages 204. In an embodiment, memory controller 202 is an example of memory chip controller 104 of FIG. 1.

In an embodiment, memory controller is coupled to and communicates with memory packages 204. In an embodiment, each memory package 204 includes multiple memory die. In an embodiment, each memory package 204 includes multiple memory die configured in a die stack.

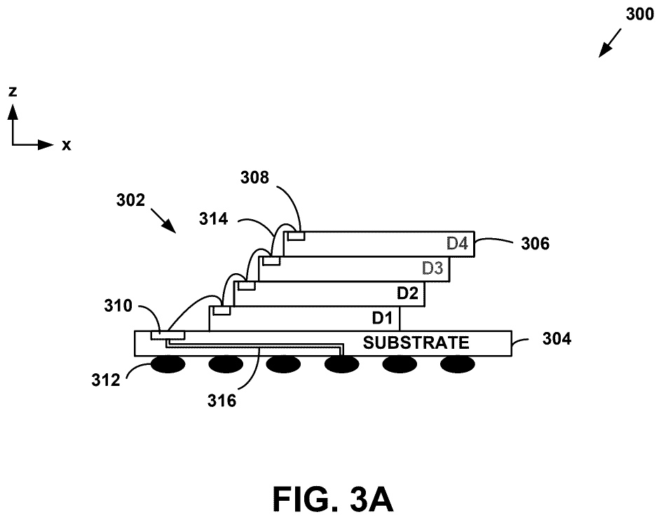

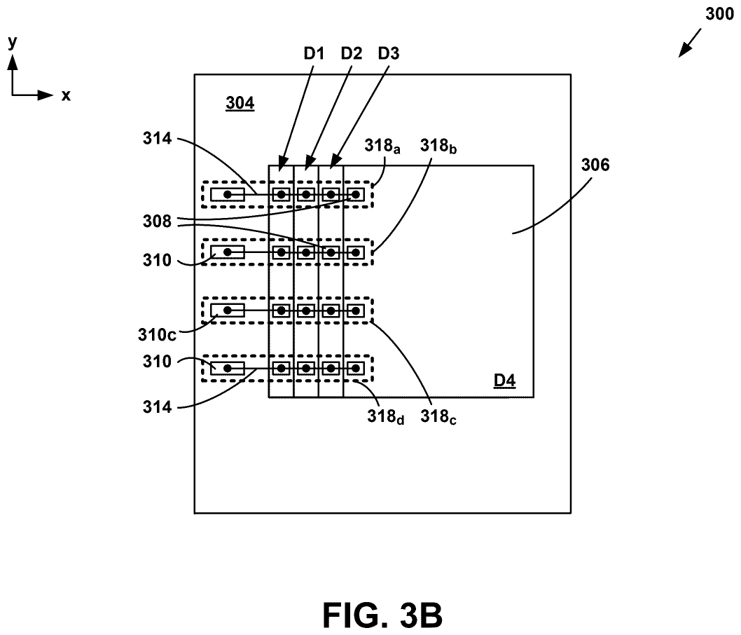

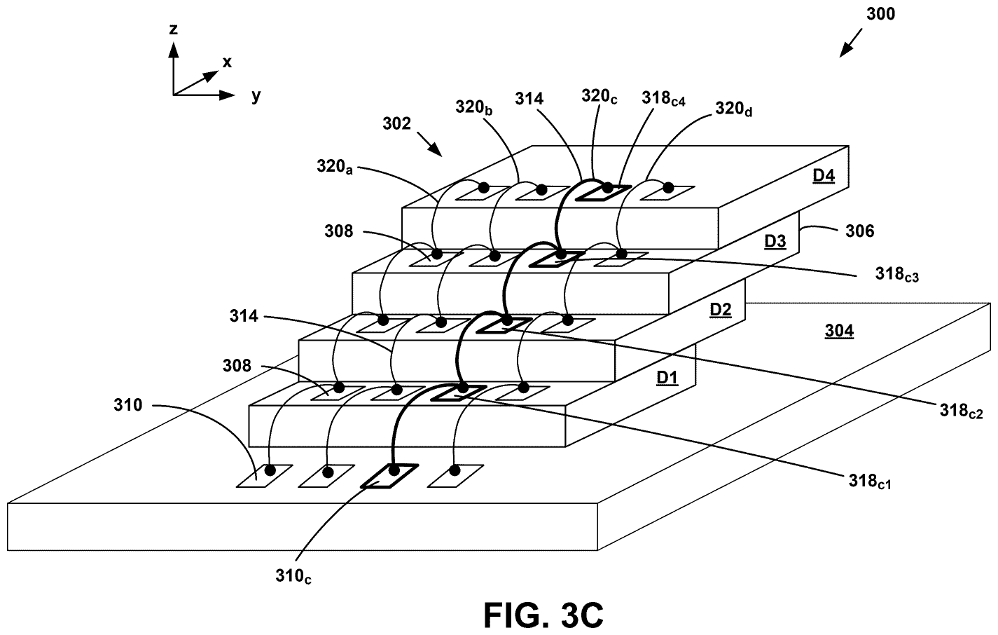

FIGS. 3A-3C depict side, top and perspective views, respectively, of a previously known semiconductor device 300 that includes a semiconductor die stack 302 formed on a substrate 304, such as a lead frame, a tape automated bonded (TAB) tape, or other similar substrate. In an embodiment, semiconductor device 300 is a memory package, such as memory package 204 of FIG. 2.

In the illustrated embodiment, die stack 302 includes four die 306 (e.g., semiconductor memory die), although more or fewer than four die 306 may be used. In embodiments, die 306 are non-volatile memory die, although the described technology is not limited to memory die.

Die 306 (e.g., D1-D4) are offset from one another in a first direction (e.g., x-direction). One or more bond pads 308 are disposed along an edge of a top surface of each die 306, one or more landing pads 310 are disposed on a top surface of substrate 304, and one or more solder balls 312 are disposed along a bottom surface of substrate 304. To avoid overcrowding the drawings, each die 306 is shown including four bond pads 308, and substrate 304 is shown including four landing pads 310.

Persons of ordinary skill in the art will understand that an integrated circuit die typically includes many more than four bond pads, and a substrate typically includes many more than four landing pads. Bond pads 308 and landing pads 310 are used to electrically interconnect die 306 to one another and to substrate 304 via wire bonds 314 (e.g., gold, gold alloy, or some other material). Substrate 304 includes one or more conductive traces 316 electrically coupling landing pads 310 to solder balls 312.

In an embodiment, rows 318 of bond pads 308 and a corresponding landing pads 310 all at the same location on each die 306 are coupled together via wire bonds 314. For example, FIG. 1B depicts rows 318ₐ-318_{d}. The wire bonds 314 in a row 318 form a shared line 320. For example, FIG. 1C depicts shared lines 320ₐ-320_{d}.

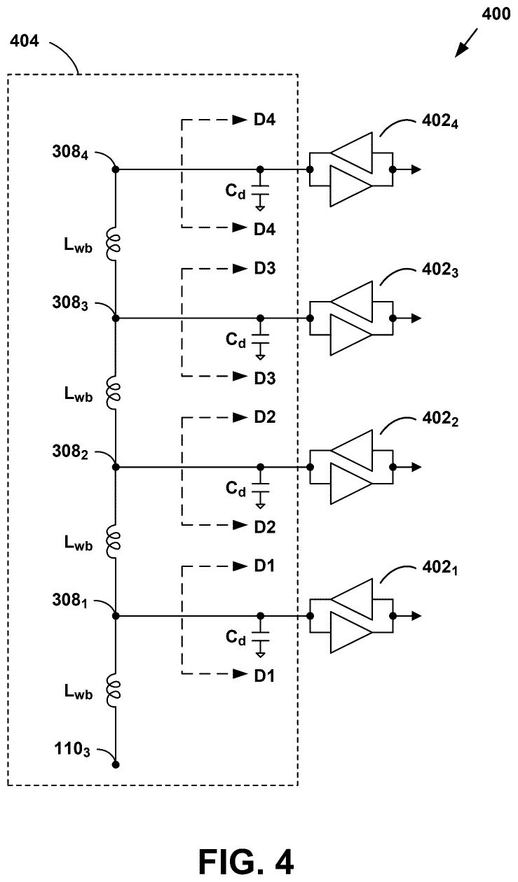

FIG. 4 is a diagram of a simplified electrical model 200 of shared line 320_{c} of FIG. 1C. In particular, looking into each die D1-D4 at the corresponding bond pad 308_{c1}-308_{c4}, respectively, the circuit is modeled as a die capacitor C_{d} to ground, coupled to a transmitter/receiver circuit 202₁-202₄, respectively. Each die capacitor C_{d} represents the parasitic capacitance of electrostatic discharge diodes (ESD) and the parasitic capacitance associated with the transmitter/receiver circuit 202. In an embodiment, wire bonds 314 are modeled primarily as an inductor having an inductance L_{wb}.

Wire bonds 314 and die capacitors C_{d} collectively form an intra-package transmission line (IPTL) 204, modeled as L-C sections. A typical value of die capacitor C_{d} is about 0.5 pF, and a typical value of wire bond inductance L_{wb} is about 0.1-0.2 nH. The characteristic impedance Z_{O} of IPTL 204 is equal to:

$${Z}_{O} = \sqrt{\frac{{L}_{wb}}{{C}_{d}}} \qquad ( 1 )$$

In this instance, the characteristic impedance Z_{O} of IPTL 204 may be about 16Ω.

In embodiments, transmitter/receiver circuits 202₁-202₄ typically transmit signals or receive signals on IPTL 204 one at a time. In other words, die D1-D4 do not all try to drive or receive signals on IPTL 204 at the same time. When one of transmitter/receiver circuits 202₁-202₄ broadcasts a signal on IPTL 204, a portion of the signal travels down IPTL 204 towards the corresponding landing pad 310. As a result of discontinuities at the junction of each wire bond 314/bond pad 308, and a portion of that transmitted signal is reflected back towards transmitter/receiver circuits 202₁-202₄. However, properly terminating IPTL 204 can reduce the magnitude of the signal reflections.

Indeed, for signals transmitted and received by transmitter/receiver circuits 202₁-202₄, maintaining signal integrity requires proper termination of IPTL 204. As used herein, “termination” refers to ending a transmission line with a device that matches the characteristic impedance of the transmission line. Typically this means using on-die termination devices that match the characteristic impedance Z_{O} of IPTL 204.

Although not depicted in FIG. 4, each of transmitter/receiver circuits 202₁-202₄ includes a selectable on-die termination device R_{ODT} for such purposes. In embodiments, on-die termination device R_{ODT} may be a passive termination device (e.g., one or more resistors coupled in parallel), an active termination device (e.g., one or more transistors configured to function as a termination device), or a combination active and passive termination device. For simplicity, on-die termination device R_{ODT} will be referred to in the remaining description as on-die termination resistance R_{ODT}.

Properly terminating an IPTL with such low impedance values of about 16Ω, however, requires using very low on-die termination resistance values (e.g., on the order of about 16Ω). Power is proportional to the square of voltage divided by resistance. As a result, driving such a low on-die termination resistance value would consume a significant amount of power. In addition, 16Ω is not a standard termination value. For example, the DDR5 protocol specifies a minimum termination value of about 34Ω, so properly terminating the IPTL would not be possible while adhering to the DDR5 protocol.

Technology is described for improving signal integrity in multi-die stacking configurations, such as described above. As described in more detail below, on each die in a die stack, a resistor is added between a bond pad and a transmitter/receiver circuit. In embodiments, the added resistor has relatively small value (e.g., 10Ω), and a resistance of a transmitter/receiver circuit is reduced by the resistance value of the added resistor. Without wanting to be bound by any particular theory, it is believed that the added resistor boosts a characteristic impedance of the IPTL. Without wanting to be bound by any particular theory, it is believed that the disclosed technology provides devices and methods to terminate on-die transmitter/receiver circuits without using very low driving strengths or low termination values.

FIGS. 3A-3C are more detailed equivalent electrical circuits 500a-500c looking into a transmitter/receiver circuit 202 (e.g., any of transmitter/receiver circuits 202₁-202₄, described above) at a bond pad 308 (such as any of bond pads 308₁-308₄ described above) during three modes of operation: transmission, high impedance and termination. Each of these will be described in turn.

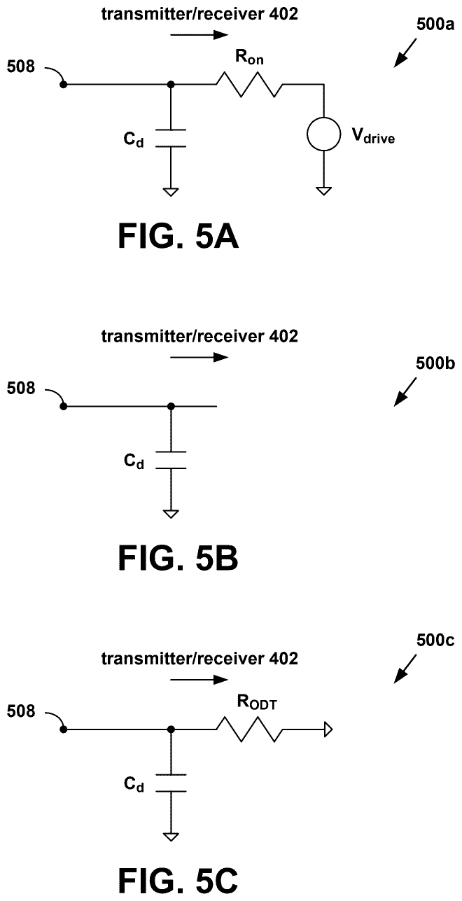

In FIG. 5A (transmission mode) transmitter/receiver circuit 202 is configured to drive a signal V_{drive} onto the IPTL. Thus, equivalent electrical circuit 500a includes a signal generator V_{drive} having at an output impedance Rₒₙ coupled to bond pad 308 and a first terminal of die capacitor C_{d}, which has a second terminal coupled to a power supply node (e.g., GND). In an embodiment, output impedance Rₒₙ may be 50Ω or some other value.

In FIG. 5B (high impedance mode), transmitter/receiver circuit 202 is configured as an open circuit. Thus, equivalent electrical circuit 500b is die capacitor C_{d} having a first terminal coupled to bond pad 308 and a second terminal coupled to a power supply node (e.g., GND).

In FIG. 5C (termination mode), transmitter/receiver circuit 202 is configured to terminate a transmission line coupled to bond pad 308. Thus, equivalent electrical circuit 500c includes an on-die termination resistance R_{ODT} having a first terminal coupled to a first terminal of die capacitor C_{d} and bond pad 308, and second terminal coupled to a second terminal of die capacitor C_{d} and a power supply node (e.g., GND).

Thus, in transmission mode transmitter/receiver circuit 202 has an output impedance Rₒₙ, and in termination mode transmitter/receiver circuit 202 has an equivalent on-die termination resistance R_{ODT}. In some embodiments, Rₒₙ=R_{ODT}. For example, in some embodiments, Rₒₙ=R_{ODT}=50Ω or some other value.

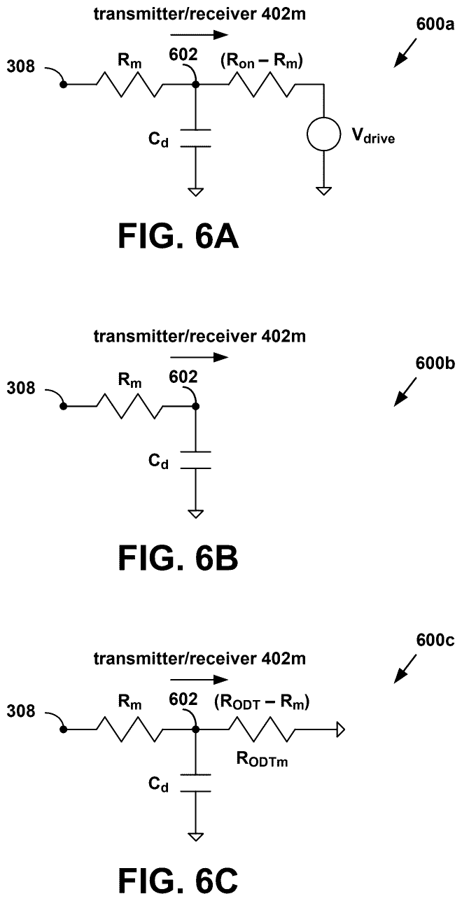

FIGS. 6A-6C are equivalent electrical circuits 600a-600c looking into a modified transmitter/receiver circuit 202m at a bond pad 308 (such as any of bond pads 308₁-308₄ described above). Modified transmitter/receiver circuit 202m is similar to transmitter/receiver circuit 202 described above, but a portion of resistance has been removed from transmitter/receiver circuit 202.

In an embodiment, a circuit element Rₘ having a resistance equal to the removed resistance is placed in series with the modified transmitter/receiver circuit 202m after die capacitor C_{d}. Circuit element Rₘ will be referred to in the remaining description as “Boosting Resistor Rₘ.” As used herein, “after die capacitor C_{d}” means disposed between die capacitor C_{d} and bond pad 308. In embodiments, Boosting Resistor Rₘ is disposed between bonding pad 308 and ESD diodes (not shown). In an embodiment, Boosting Resistor Rₘ may have a resistance of about 10Ω or some other value.

For example, FIG. 6A depicts modified transmitter/receiver circuit 202m in transmission mode for driving a signal V_{drive} onto the IPTL. Thus, equivalent electrical circuit 600a includes a signal generator V_{drive} having a modified output impedance Rₒₙₘ=(Rₒₙ−Rₘ) coupled at node 602 to a first terminal of die capacitor C_{d}, which has a second terminal coupled to a power supply node (e.g., GND). Boosting Resistor Rₘ has a first terminal coupled to bond pad 308 and a second terminal coupled to node 602.

Thus, modified transmitter/receiver circuit 202m is the same as transmitter/receiver circuit 202m, but with a modified output impedance Rₒₙₘ equal to (Rₒₙ−Rₘ), where Rₒₙ is a desired output impedance. At DC, the output impedance of equivalent electrical circuit 600a is equal to (Rₒₙ−Rₘ)+Rₘ=Rₒₙ, the same as equivalent electrical circuit 500a of FIG. 5A.

In an embodiment output impedance Rₒₙ may be 50Ω and Boosting Resistor Rₘ=10Ω, and thus modified output impedance Rₒₙₘ=40Ω. Persons of ordinary skill in the art will understand that other values may be used for desired output impedance Rₒₙ, Boosting Resistor Rₘ, and modified output impedance Rₒₙₘ.

FIG. 6B depicts modified transmitter/receiver circuit 202m configured as an open circuit. Thus, in equivalent electrical circuit 600b Boosting Resistor Rₘ has a first terminal coupled to bond pad 308 and a second terminal coupled to node 602 and a first terminal of die capacitor C_{d}, which has a second terminal coupled to a power supply node (e.g., GND). At DC, the input impedance of equivalent electrical circuit 600b is infinite, the same as equivalent electrical circuit 500b of FIG. 5B.

FIG. 6C depicts modified transmitter/receiver circuit 202m configured in termination mode. In the equivalent electrical circuit 600c, Boosting Resistor Rₘ has a first terminal coupled to bond pad 308 and a second terminal coupled to node 602. Die capacitor C_{d} has a first terminal coupled to node 602 and a second terminal coupled to a power supply node (e.g., GND).

A modified on-die termination resistance R_{ODTm} has a value R_{ODTm}=(R_{ODT}−Rₘ), and has a first terminal coupled to node 602 and a second terminal coupled to a power supply node (e.g., GND). At DC, the input impedance of equivalent electrical circuit 600c is Rₘ+(R_{ODT}−Rₘ)=R_{ODT}, the same as equivalent electrical circuit 500c of FIG. 5C.

In an embodiment on-die termination resistance R_{ODT} may be 50Ω and Boosting Resistor Rₘ=10Ω, and thus modified on-die termination resistance R_{ODTm}=40Ω. Persons of ordinary skill in the art will understand that other values may be used for desired on-die termination resistance R_{ODT}, Boosting Resistor Rₘ, and modified on-die termination resistance R_{ODTm}.

Thus, in transmission mode at DC modified transmitter/receiver circuit 202m has an output impedance Rₒₙ, and in termination mode modified transmitter/receiver circuit 202m has an equivalent on-die termination resistance R_{ODT}, the same as transmitter/receiver circuit 202m of FIGS. 3A and 3C.

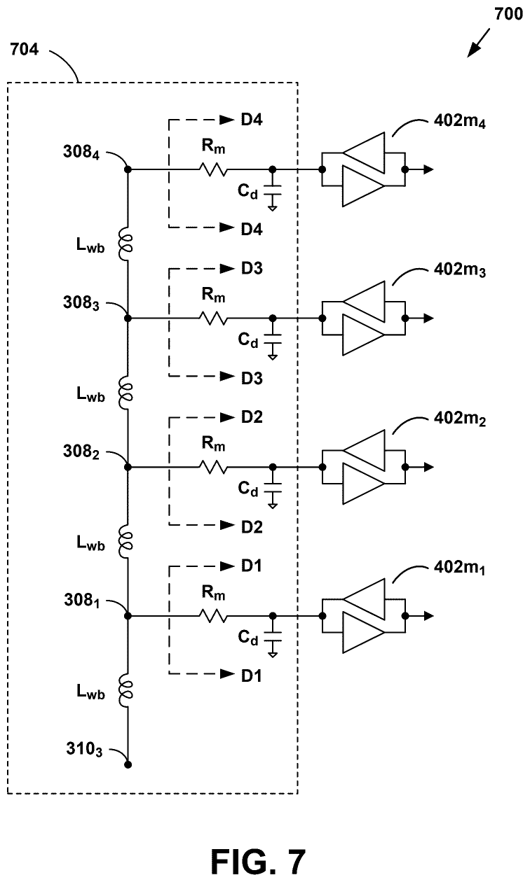

FIG. 7 is a diagram of a simplified electrical model 700 of a shared line of FIG. 1C, but with each die D1-D4 including Boosting Resistor Rₘ and modified transmitter/receiver circuit 202m. Wire bonds 314, Boosting Resistors Rₘ and die capacitors C_{d} collectively form an IPTL 704, modeled as L-R-C sections. As with model 200 of FIG. 4, a typical value of die capacitor C_{d} is about 0.5 pF, and a typical value of wire bond inductance L_{wb} is about 0.1-0.2 nH. As described above, in an embodiment Boosting Resistor Rₘ=10Ω.

Persons of ordinary skill in the art will understand that the characteristic impedance Z_{Om} of IPTL 704 is equal to:

$${Z}_{Om} = \sqrt{\frac{{L}_{wb}}{{C}_{d}} ( 1 + {R}_{m} j ω {C}_{d} )} \qquad ( 2 )$$

Comparing Equation (2) with Equation (1), the effect of Boosting Resistor Rₘ is that a boosting factor (1+RₘjωC_{d}) increases the characteristic impedance Z_{Om} of IPTL 704 of FIG. 7 compared with the characteristic impedance Z_{O} of IPTL 204 of FIG. 4.

Using the example values above for wire bond inductance L_{wb}, die capacitor C_{d}, and Boosting Resistor Rₘ, in the frequency range 0.4-4 GHz the characteristic impedance of IPTL 704 of FIG. 7 is Z_{Om}=34Ω, compared with the characteristic impedance of IPTL 204 of FIG. 4 (Z_{O}=16Ω). This increased value is more practical to terminate, consumes less power, and fits within a range of standard termination values.

Without wanting to be bound by any particular theory, it is believed that removing a portion of a resistance from transmitter/receiver circuit 202, and placing a Boosting Resistor Rₘ having a value equal to the removed resistance in series with the modified transmitter/receiver circuit 202m may improve signal integrity in die stacking technology.

Indeed, simulation results show that stripping a small resistance out of the transceiver and using it at the back-end (to interface the pad opening and the ESD diodes) can increase the characteristic impedance of the intra-package routing, which in turn reduces the reflection from the sensitive nodes and improves the overall signal quality.

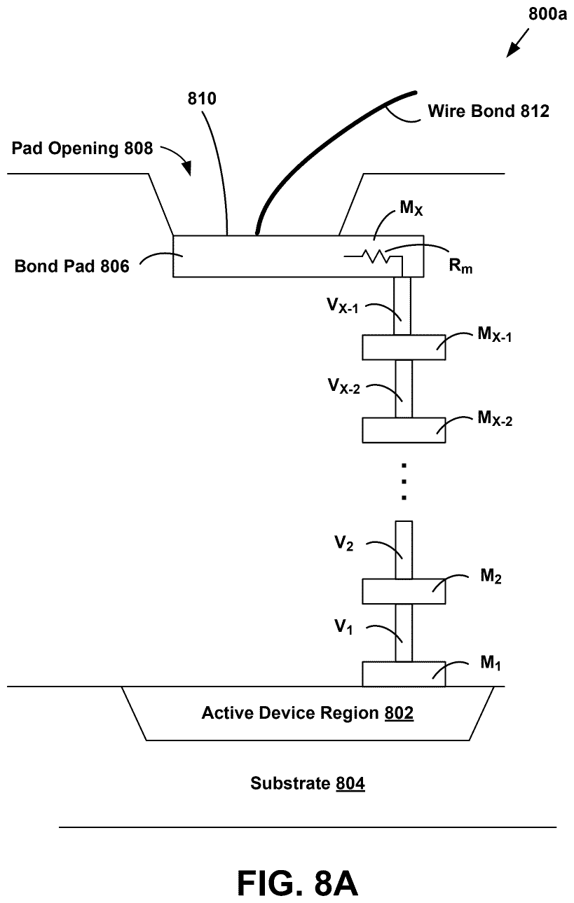

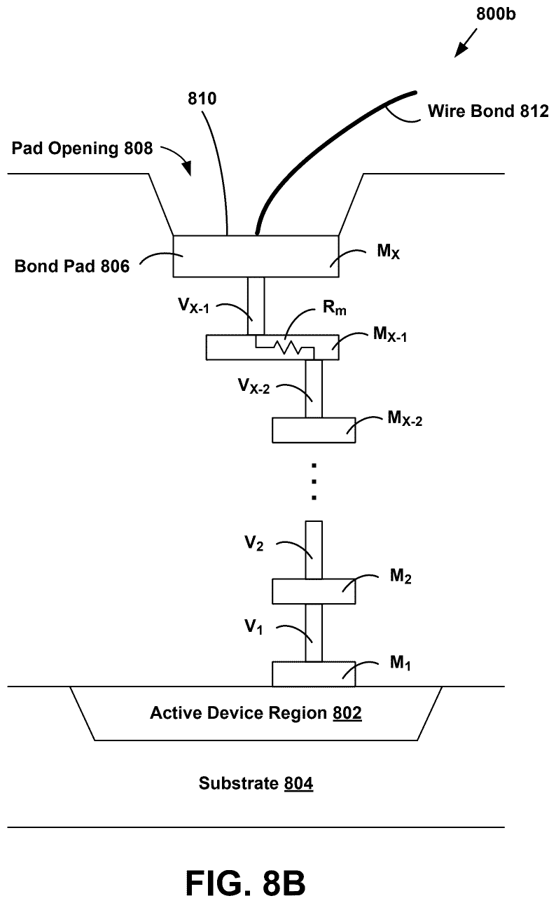

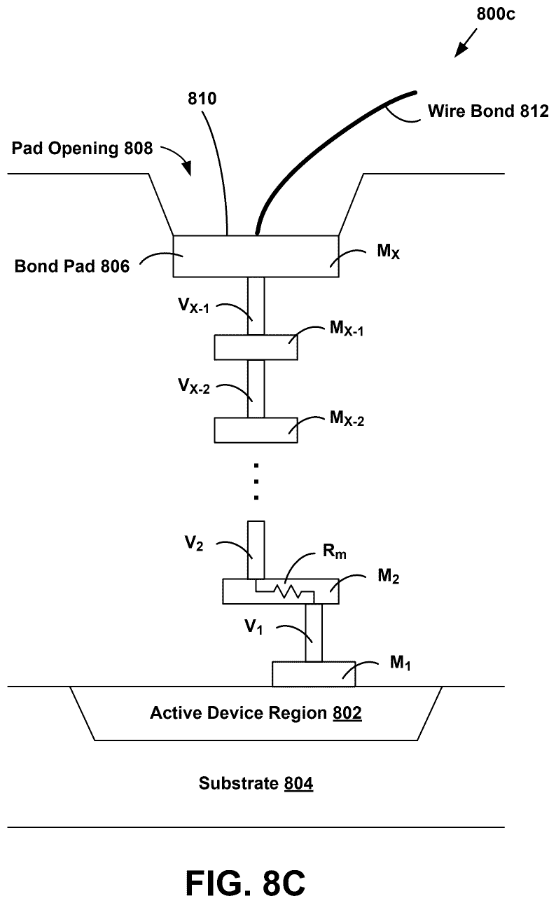

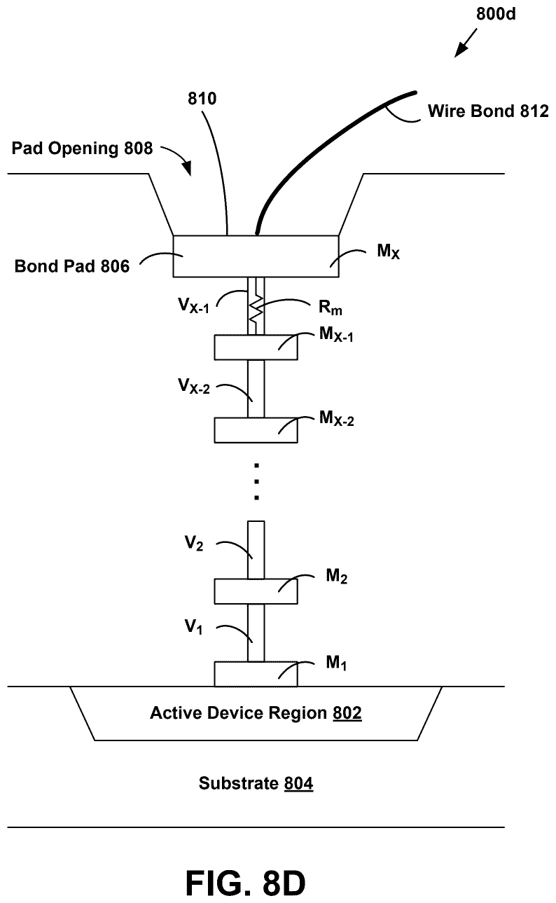

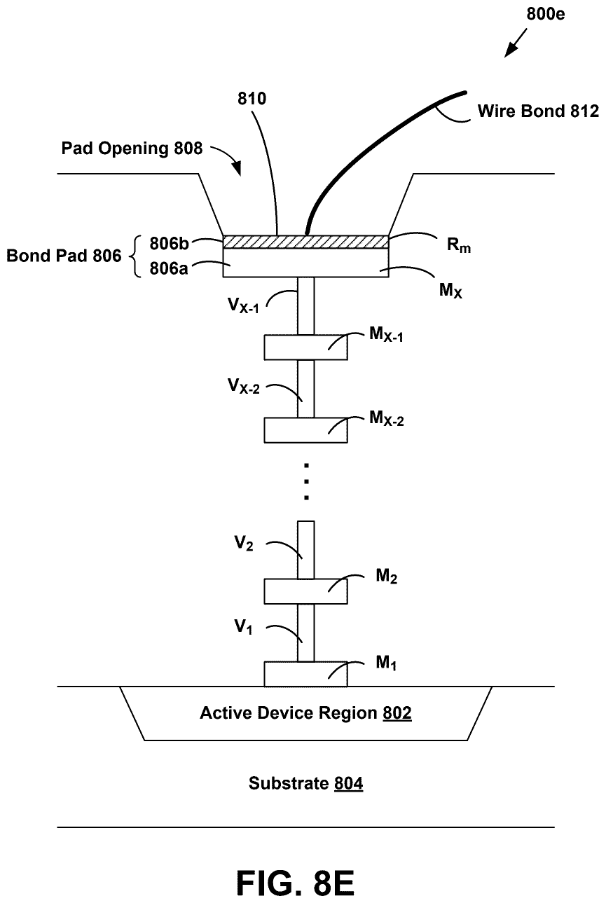

FIGS. 8A-8E are simplified diagrams depicting various techniques that may be used to implement Boosting Resistor Rₘ. FIG. 8A is a simplified cross-sectional view of a portion of a semiconductor die 800a. An active device region 802 is formed within a semiconductor substrate 804. In embodiments, active device region 802 may include diodes (include ESD diodes), transistors, passive circuit elements such as resistors and capacitors, and other similar circuits.

In embodiments, a series of metal layers M₁, M₂, . . . , M_{X-2}, M_{X-1}, M_{X} are formed above active device region 802 and substrate 804. Metal layer M₁ is the lowest metal layer and metal layer M_{X} is the uppermost metal layer. Metal layer M_{X} will also be referred to herein an top metal layer M_{X}. In embodiments, a series of vias V₁, V₂, . . . , V_{X-2}, V_{X-1} are used to interconnect the various metal layers M₁, M₂, . . . , M_{X-2}, M_{X-1}, M_{X}. For example, via V₁ interconnects metal layers M₁ and M₂, via V_{X-2} interconnects metal layers M_{X-2} and M_{X-1}, and so on.

In an embodiment, a bond pad 806 is formed in top metal layer M_{X}, and a pad opening 808 is formed above and exposes a top surface 810 of bond pad 806. A wire bond 812 is coupled to top surface 810 of bond pad 806. In the embodiment of FIG. 8A, Boosting Resistor Rₘ is implemented in a top metal layer (e.g., top metal layer M_{X}) beneath pad opening 808. For example, a length of top metal layer M_{X} having a resistance equal to a desired resistance of Boosting Resistor Rₘ may be coupled to and disposed beneath the pad opening.

In other embodiments, Boosting Resistor Rₘ may be implemented in a lower metal layer (e.g., any of metal layers M₁, M₂, . . . , M_{X-2}, M_{X}) after ESD diodes. For example, FIG. 8B depicts a semiconductor die 800b, similar to semiconductor die 800a of FIG. 8A. However, in semiconductor die 800b Boosting Resistor Rₘ is implemented in metal layer M_{X-1}. Likewise, FIG. 8C depicts a semiconductor die 800c, similar to semiconductor die 800a of FIG. 8A. However, in semiconductor die 800c Boosting Resistor Rₘ is implemented in metal layer M₂.

In still other embodiments, Boosting Resistor Rₘ may be implemented in one or more of metal layers M₁, M₂, . . . , M_{X-2}, M_{X} after ESD diodes. For example, a first portion of Boosting Resistor Rₘ may be implemented in a first metal layer (e.g., metal layer M₁) and a second portion of Boosting Resistor Rₘ may be implemented in a second metal layer (e.g., metal layer M_{X-1}), and so on.

In another alternative embodiment, Boosting Resistor Rₘ may be implemented in one of vias V₁, V₂, . . . , V_{X-2}, V_{X-1}. For example, FIG. 8D depicts a semiconductor die 800d, similar to semiconductor die 800a of FIG. 8A. However, in semiconductor die 800d Boosting Resistor Rₘ is implemented in via V_{X-1}. For example, a length and/or width of via V_{X-1} may be specified so that via V_{X-1} has a resistance equal to a desired resistance of Boosting Resistor Rₘ.

In other embodiments, Boosting Resistor Rₘ may be implemented in one or more of vias V₁, V₂, . . . , V_{X-2}, V_{X-1}. For example, a first portion of Boosting Resistor Rₘ may be implemented in a first via (e.g., via V_{X-2}) and a second portion of Boosting Resistor Rₘ may be implemented in a second via (e.g., via V_{X-1}), and so on.

In another alternative embodiment, Boosting Resistor Rₘ may be implemented as part of bond pad 806. For example, FIG. 8E depicts a semiconductor die 800e, similar to semiconductor die 800a of FIG. 8A. However, in semiconductor die 800e bond pad 806 is a multi-layer bond pad having a first layer 806a and a second layer 806b disposed above first layer 806a. In an embodiment, first layer 806a may be a top metal layer M_{X}, and second layer 806b may be another material layer disposed above top metal layer M_{X}. In an embodiment, second layer 806b may be specified to have a resistance equal to a desired resistance of Boosting Resistor Rₘ.

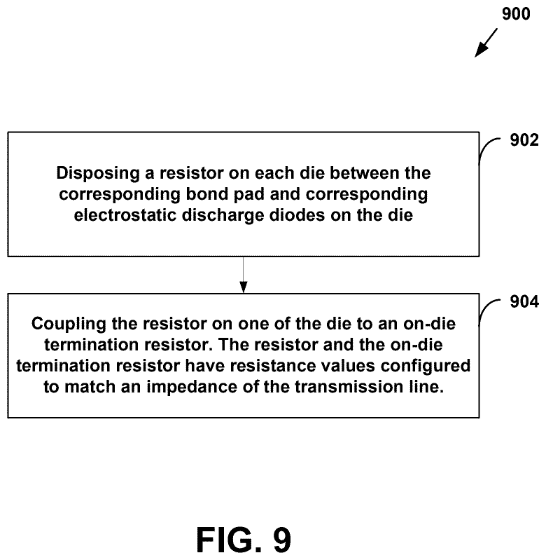

FIG. 9 is a block diagram of a method 900 of terminating a transmission line in a die stack above a substrate, the transmission line including wire bonds coupled between bond pads on each die in the die stack.

At step 902, disposing a resistor on each die between the corresponding bond pad and corresponding electrostatic discharge diodes on the die.

At step 904, coupling the resistor on one of the die to an on-die termination resistor. The resistor and the on-die termination resistor have resistance values configured to match an impedance of the transmission line.

One embodiment includes an apparatus that includes a die stack that includes multiple die disposed above a substrate. Each die includes a bond pad, a resistor and a transmitter/receiver circuit, and wire bonds connect the bond pads of the multiple die. Each resistor is coupled between a corresponding one of the bond pads and a corresponding one of the transmitter/receiver circuits. The resistors are configured to increase an impedance of a transmission line that includes the wire bonds.

One embodiment includes an apparatus that includes a die stack that includes multiple die disposed above a substrate. Each die includes a bond pad, a resistor and a capacitor that includes a parasitic die capacitance, and wire bonds connect the bond pads of the multiple die. Each resistor is disposed between a corresponding one of the bond pads and a corresponding one of the capacitors. The resistors are configured to increase an impedance of a transmission line that includes the wire bonds and the capacitors.

One embodiment includes a method of terminating a transmission line in a die stack above a substrate, the transmission line including wire bonds coupled between bond pads on each die in the die stack. The method includes disposing a resistor on each die between the corresponding bond pad and corresponding electrostatic discharge diodes on the die, and coupling the resistor on one of the die to an on-die termination resistor. The resistor and the on-die termination resistor have resistance values configured to match an impedance of the transmission line.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

For purposes of this document, the terms “top” and “bottom,” “upper” and “lower” and “vertical” and “horizontal” as may be used herein are by way of example and illustrative purposes only, and are not meant to limit the description of the technology inasmuch as the referenced item can be exchanged in position and orientation. Also, as used herein, the terms “substantially,” “approximately” and/or “about” mean that the specified dimension or parameter may be varied within an acceptable manufacturing tolerance for a given application. In an embodiment, the acceptable manufacturing tolerance is ±0.25%. As used herein the term “semiconductor die” or simply “die” may refer to one or more semiconductor die.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

1. An apparatus comprising:
a die stack comprising a plurality of die disposed above a substrate, each die comprising a bond pad and a transmitter/receiver circuit;
a plurality of wire bonds connecting the bond pads of the plurality of die; and
a plurality of resistors each coupled between a corresponding one of the bond pads and a corresponding one of the transmitter/receiver circuits,
wherein the plurality of resistors are configured to increase an impedance of a transmission line comprising the wire bonds.

2. The apparatus of claim 1, wherein each die comprises a top metal layer comprising a corresponding one of the resistors.

3. The apparatus of claim 1, wherein:
each die comprises a plurality of metal layers; and
one or more of the metal layers comprises a corresponding one of the resistors.

4. The apparatus of claim 1, wherein:
each die comprises a plurality of metal layers coupled by a plurality of vias; and
one or more of the vias comprises a corresponding one of the resistors.

5. The apparatus of claim 1, wherein each of the resistors is disposed below a corresponding one of the bond pads.

6. The apparatus of claim 1, wherein:
each bond pad comprises a plurality of bond pad layers; and
one or more of the layers comprises a corresponding one of the resistors.

7. The apparatus of claim 1, wherein:
each die comprises electrostatic discharge diodes; and
each resistor is disposed between a corresponding one of the bond pads and a corresponding one of the electrostatic discharge diodes.

8. The apparatus of claim 1, wherein the transmission line comprises the resistors.

9. The apparatus of claim 1, wherein the transmission line comprises a capacitance of each transmitter/receiver circuit.

10. The apparatus of claim 1, wherein:
each transmitter/receiver circuit comprises a transmitter output impedance; and
a sum of the output impedance and an impedance of the corresponding resistor is configured to match an impedance of the transmission line.

11. The apparatus of claim 1, wherein:
each transmitter/receiver circuit comprises an on-die termination device comprising an impedance; and
a sum of the impedance of the on die termination device and an impedance of the corresponding resistor is configured to match an impedance of the transmission line.

12. The apparatus of claim 1, wherein each die comprises a non-volatile memory die.

13. The apparatus of claim 1, wherein the die stack comprises four or more non-volatile memory die.

14. An apparatus comprising:
a die stack comprising a plurality of die disposed above a substrate, each die comprising a bond pad and a capacitor comprising a parasitic die capacitance;
a plurality of wire bonds connecting the bond pads of the plurality of die; and
a plurality of resistors each disposed between a corresponding one of the bond pads and a corresponding one of the capacitors,
wherein the plurality of resistors are configured to increase an impedance of a transmission line comprising the wire bonds and capacitors.

15. The apparatus of claim 14, wherein:
each die comprises a plurality of metal layers; and
one or more of the metal layers comprises a corresponding one of the resistors.

16. The apparatus of claim 14, wherein each of the resistors is disposed below a corresponding one of the bond pads.

17. The apparatus of claim 14, wherein:
each die comprises electrostatic discharge diodes; and
each resistor is disposed between a corresponding one of the bond pads and a corresponding one of the electrostatic discharge diodes.

18. The apparatus of claim 14, wherein:
each die further comprises a transmitter/receiver circuit comprising a transmitter output impedance; and
a sum of the output impedance and an impedance of the corresponding resistor is configured to match an impedance of the transmission line.

19. The apparatus of claim 14, wherein:
each die further comprises a transmitter/receiver circuit comprising an on-die termination device comprising an impedance; and
a sum of the impedance of the on die termination device and an impedance of the corresponding resistor is configured to match an impedance of the transmission line.

20. A method comprising:
terminating a transmission line in a die stack above a substrate, the transmission line comprising wire bonds coupled between bond pads on each die in the die stack, by:
disposing a resistor on each die between the corresponding bond pad and corresponding electrostatic discharge diodes on the die; and
coupling the resistor on one of the die to an on-die termination resistor,
wherein the resistor and the on-die termination resistor have resistance values configured to match an impedance of the transmission line.
